(19) United States
(12) Patent Application Publication
(10) Pub. No.: US 2023/0162971 A1
(43) Pub. Date: May 25, 2023

(54) METHOD OF FORMING SIOC AND SIOCN LOW-K SPACERS

(71) Applicant: ASM IP Holding B.V., Almere (NL)

(72) Inventors: Zecheng Liu, Inagi-shi (JP); Viljami Pore, Helsinki (FI)

(21) Appl. No.: 17/990,776

(22) Filed: Nov. 21, 2022

Related U.S. Application Data
(60) Provisional application No. 63/283,163, filed on Nov. 24, 2021.

(51) Int. Cl. H01L 21/02; C23C 16/40; C23C 16/455

(52) U.S. Cl. CPC H01L 21/02104; C23C 16/401; C23C 16/45536

(57) ABSTRACT

Methods for depositing SiOC and SiOCN films are disclosed. Exemplary methods utilize precursors containing iodine and alkoxide, and can be used to form low-k spacers using O-free PEALD.

### CROSS-REFERENCE TO RELATED APPLICATIONS

This application claims priority to U.S. Provisional Patent Application Ser. No. 63/283,163 filed Nov. 24, 2021 and titled METHOD OF FORMING SIOC AND SIOCN LOW-K SPACERS, the disclosure of which is hereby incorporated by reference in its entirety.

### FIELD OF INVENTION

The present disclosure generally relates to improved methods for depositing silicon oxycarbide (SiOC) and silicon oxycarbonitride (SiOCN) films.

### BACKGROUND OF THE DISCLOSURE

During the manufacture of semiconductor devices, the need for improved techniques for forming integrated spacers increases as the devices are scaled down. A conformality above 95%, low dielectric constant (low-k), good electrical isolation, low wet etch rate (preferably below 1 Å/min in a 0.5% diluted hydrofluoric acid (HF) solution), and no metal oxidation when metals are pre-deposited before deposition of spacers are desired. Silicon nitride (SiN) is generally the most widely used integrated spacer due to its high thermal stability and good etch selectivity. However, the dielectric constant of SiN is around 7.5, which is undesirably high, and can result in suppressed resistance capacitance (RC) delay due to parasitic capacitance in smaller devices. In current logic applications, the moderate scaling of gate spacer thickness (6 to 4 nm) generally requires a low-k value below 3.5 for better intrinsic performance. Also, memory devices like DRAM generally require bit line (BL) spacers with a low-k value below 4.4 and a high thermal stability.

Silicon oxycarbide (SiOC) and silicon oxycarbide nitride (SiOCN) films can be deposited with high conformality. The Si—O bonds yields a dielectric constant around 3.9, and the additional Si—C bonding can dramatically reduce the wet etch rate (WER) for improved etch selectivity.

Different deposition methods have previously been shown to yield different SiOC film qualities. For example, PECVD has been shown to yield highly dense SiOC films with true Si—C bonding, but does not yield good conformality when the pitch is small. As another example, using O-free PEALD with H₂ plasma and alkoxide-containing Si precursors has been shown to form SiOC films with Si—C bonding, but the sidewall quality is not desirable due to a weak energetic ion-induced densification. Therefore, improved methods for forming low-k spacers are desired.

Any discussion of problems and solutions set forth in this section has been included in this disclosure solely for the purposes of providing a context for the present disclosure, and should not be taken as an admission that any or all of the discussion was known at the time the invention was made.

### SUMMARY OF THE DISCLOSURE

Exemplary embodiments of this disclosure provide methods for depositing SiOC and SiOCN films. While the ways in which various embodiments of the present disclosure address drawbacks of prior methods are discussed in more detail below, in general, various embodiments of the disclosure provide methods for depositing low-k SiOC and SiOCN films using Si precursors containing iodine and alkoxide.

In accordance with examples of the disclosure, a method of depositing a material on a surface of a substrate comprises providing the substrate within a reaction chamber; providing a precursor represented by a chemical formula comprising silicon, at least one iodine, and at least one functional group comprising carbon and oxygen within the reaction chamber; and providing a plasma within the reaction chamber.

In various embodiments, the oxygen is bonded to the silicon and the carbon. In various embodiments, the at least one functional group comprising carbon and oxygen comprises one or more of a C1-C6 alkyl group and a C6 aryl group. In various embodiments, the precursor is represented by a general formula I:

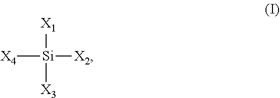

wherein at least one of X₁, X₂, X₃, and X₄ is iodine of the at least one iodine, and at least one of X₁, X₂, X₃, and X₄ is a functional group comprising carbon and oxygen of the at least one functionals group comprising carbon and oxygen. In various embodiments, two of X₁, X₂, X₃, and X₄ are iodine of the at least one iodine, and two of X₁, X₂, X₃, and X₄ are a functional group containing carbon and oxygen of the at least one functional group comprising carbon and oxygen. In various embodiments, three of X₁, X₂, X₃, and X₄ are iodine of the at least one iodine, and one of X₁, X₂, X₃, and X₄ is a functional group containing carbon and oxygen of the at least one functional group comprising carbon and oxygen.

In various embodiments, the functional group comprising carbon and oxygen comprises a C1-C6 alkoxide, or a C1-C4 alkoxide, or a C1-C3 alkoxide.

In various embodiments, the precursor comprises one or more of triethoxyiodosilane, iodotriphenoxysilane, [(triiodosilyl)oxy]benzene, triiodopropoxysilane, ethoxytriiodosilane, triiodomethoxysilane, diiododiphenoxysilane, diiododipropoxysilane, diiododimethoxysilane, iodotripropoxysilane, and iodotrimethoxysilane.

In various embodiments, the step of providing the plasma does not comprise providing an oxidant to the reaction chamber. In various embodiments, the plasma is formed by flowing one or more of H₂, N₂, and NH₃ to the reaction chamber.

In various embodiments, the method comprises a plasma enhanced cyclic (e.g., atomic layer deposition) process.

In various embodiments, the method further comprises purging the reaction chamber after providing the precursor. In various embodiments, the method further comprises purging the reaction chamber after providing the plasma. In some embodiments, no RF power is provided to the reaction chamber while purging the reaction chamber.

In various embodiments, a temperature within the reaction chamber is between about 100 and about 500° C., between about 200 and about 400° C., or between about 250 and about 350° C. In various embodiments, a pressure within the reaction chamber is between about 300 and 1000 Pa, or between about 1000 and about 3000 Pa.

In various embodiments, the material comprises one or more of silicon oxycarbide and silicon oxycarbide nitride.

In various embodiments, the method forms a spacer on a substrate.

In accordance with further embodiments of the disclosure, a device structure is provided. The device structure can be formed according to a method as set forth herein.

In accordance with yet additional examples of the disclosure, a system configured to perform a method and/or form a device structure as described herein is provided.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a surface reaction mechanism in accordance with previously known methods.

FIG. 2 illustrates a film deposition method in accordance with at least one embodiment of the disclosure.

FIG. 3 illustrates a structure in accordance with at least one embodiment of the disclosure.

FIG. 4 illustrates a system in accordance with at least one embodiment of the disclosure.

FIG. 5 illustrates another structure in accordance with at least one embodiment of the disclosure.

FIG. 6 illustrates a timing sequence in accordance with at least one embodiment of the disclosure

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses described herein and obvious modifications and equivalents thereof. Thus, it is intended that the scope of the invention disclosed should not be limited by the particular disclosed embodiments described below.

As used herein, the terms “substrate” may refer to a wafer or any underlying material or materials that may be used to form, or upon which, a device, a circuit, or a film may be formed. Further, the substrate can include various features, such as recesses, lines, and the like formed within or on at least a portion of a layer of the substrate.

In some embodiments, the terms “film” and “layer” may be used interchangeably and refer to a layer extending in a direction perpendicular to a thickness direction to cover an entire target or concerned surface, or simply a layer covering a target or concerned surface. In some embodiments, the terms “film” or “layer” refer to a structure having a certain thickness formed on a surface. A film or layer may be constituted by a discrete single film or layer having certain characteristics. Alternatively, a film or layer may be constituted of multiple films or layers, and a boundary between adjacent films or layers may or may not be clear and may or may not be established based on physical, chemical, and/or any other characteristics, formation processes or sequence, and/or functions or purposes of the adjacent films or layers.

In some embodiments, “gas” can include material that is a gas at normal temperature and pressure, a vaporized solid and/or a vaporized liquid, and may be constituted by a single gas or a mixture of gases, depending on the context. A gas can include a process gas, an etch gas or other gas that passes through the substrate processing device, such as through a susceptor, a shower plate, a gas distribution device, a gas supply apparatus, an electrode, or the like.

In some embodiments, the term “precursor” refers generally to a compound that participates in the chemical reaction that produces another compound, and particularly to a compound that constitutes a film matrix or a main skeleton of a film, whereas the term “reactant” refers to a compound, other than precursors, that activates a precursor, modifies a precursor, or catalyzes a reaction of a precursor, wherein the reactant may provide an element (such as H and/or N) to a film matrix and become a part of the film matrix, when RF power is applied.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments. Percentages set forth herein are absolute percentages, unless otherwise noted.

It shall be understood that the term “comprising” is open ended and does not exclude the presence of other elements or components, unless the context clearly indicates otherwise. The term “comprising” includes the meaning of “consisting of.” The term “consisting of” indicates that no other features or components are present than those mentioned, unless the context indicates otherwise.

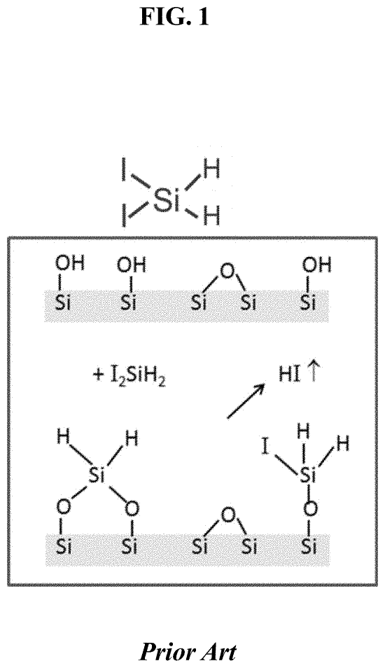

In a PEALD SiN process, I₂SiH₂ precursor has been shown to form dense surface species on sidewalls at the precursor feed step at higher temperatures of 350-400° C. The surface reaction is shown in FIG. 1. The I₂SiH₂ precursor is unique due to the instability of iodine at high temperatures.

Described herein are methods for depositing a material on a substrate using Si precursors which contain iodine and alkoxide. By using iodine, sidewall quality may be improved during the precursor feed step at a high temperature, e.g. 500° C. Moreover, alkoxide ligands avoid the utilization of oxidative plasma, thereby preventing metal-oxidations. In some embodiments, the methods form a spacer on a substrate.

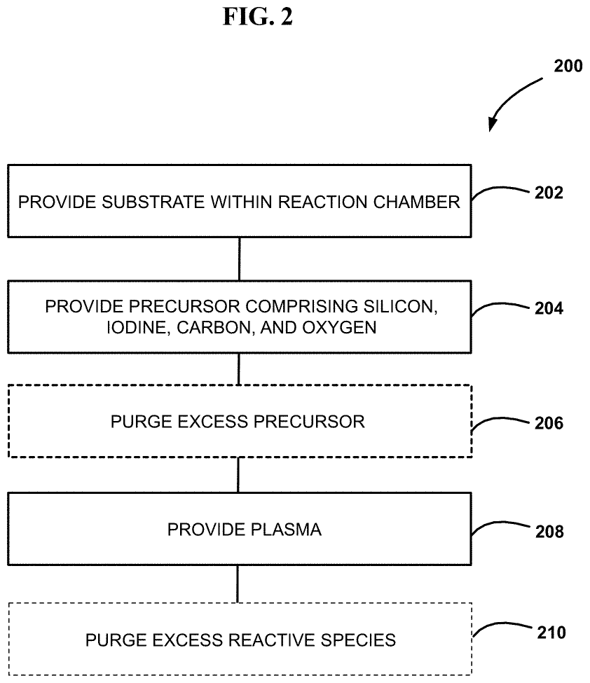

FIG. 2 illustrates a method 200 of depositing a material on a surface of a substrate according to an embodiment of the disclosure. Method 200 includes the steps of providing a substrate within a reaction chamber (step 202), providing a precursor comprising silicon, iodine, carbon, and oxygen to the reaction chamber (step 204), purging excess precursor from the reaction chamber (step 206), providing a plasma within the reaction chamber (step 208), and purging excess reactive species from the reaction chamber (step 210).

During step 202, a substrate is provided within a reaction chamber. A temperature within the reaction chamber can be brought to a temperature and pressure for subsequent processing. In various embodiments, the temperature within the reaction chamber is between about 100° C. and about 500° C., between about 200° C. and about 400° C., or between about 250° C. and about 350° C. In various embodiments, the pressure within the reaction chamber is between about 300 Pa and 1000 Pa, or between about 1000 Pa and about 3000 Pa.

During step 204, a precursor comprising silicon, iodine, carbon, and oxygen is provided to the reaction chamber. In various embodiments, the precursor includes silicon, at least one iodine, and at least one functional group comprising carbon and oxygen. In various embodiments, the oxygen is bonded to the silicon and the carbon. In various embodiments, the at least one functional group comprising carbon and oxygen comprises one or more of a C1-C6 alkyl group and a C6 aryl group. In various embodiments, the precursor is represented by a general formula I:

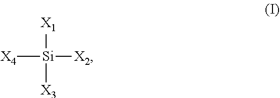

wherein at least one of X₁, X₂, X₃, and X₄ is iodine of the at least one iodine, and at least one of X₁, X₂, X₃, and X₄ is a functional group comprising carbon and oxygen of the at least one functionals group comprising carbon and oxygen. In some embodiments, in general formula I, at least two of X₁, X₂, X₃, and X₄ are iodine of the at least one iodine, and two of X₁, X₂, X₃, and X₄ are a functional group containing carbon and oxygen of the at least one functional group comprising carbon and oxygen. In some embodiments, in general formula I, three of X₁, X₂, X₃, and X₄ are iodine of the at least one iodine, and one of X₁, X₂, X₃, and X₄ is a functional group containing carbon and oxygen of the at least one functional group comprising carbon and oxygen

A flow rate of the precursor during step 204 may be between about 50 and about 1000 sccm. A duration of step 204 can be between about 0.15 and about 4 seconds.

In some embodiments, the functional group comprising carbon and oxygen comprises a C1-C6 alkoxide, or a C1-C4 alkoxide, or a C1-C3 alkoxide.

In preferred embodiments, the precursor comprises one or more of the compounds shown in Table 1.

TABLE 1

| | |
|---|---|
| Triethoxyiodosilane | 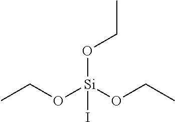 |
| Silane, iodotriphenoxy- | 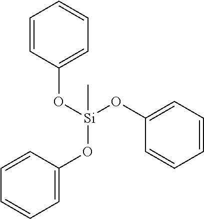 [SMILES: C[Si](Oc1ccccc1)(Oc1ccccc1)Oc1ccccc1] |
| [(Triiodosilyl)oxy]benzene | 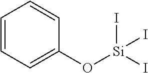 [SMILES: I[Si](I)(I)Oc1ccccc1] |
| Triiodopropoxysilane | 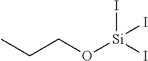 |
| Ethoxytriiodosilane | 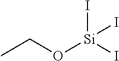 |
| Triiodomethoxysilane | 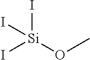 |
| Silane, diiododiphenoxy- | 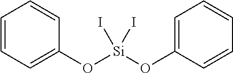 [SMILES: I[Si](I)(Oc1ccccc1)Oc1ccccc1] |
| Diiododipropoxysilane | 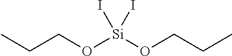 |
| Diiododimethoxysilane | 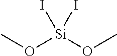 |
| Iodotripropoxysilane | 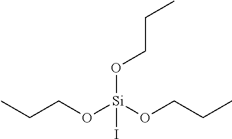 |
| Iodotrimethoxysilane | 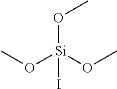 |

During optional step 206, excess precursor is purged from the reaction chamber.

During step 208, a plasma is provided to the reaction chamber. In preferred embodiments, the plasma is an H₂ plasma, a N₂ plasma, an NH₃ plasma, or an N₂+H₂ plasma. That is, the plasma is formed by providing a reactant gas comprising H₂, N₂, NH₃, or a combination of N₂ and H₂ to the reaction chamber and forming a plasma using a plasma power. A flow rate of the reactant gas may be between about 10 and 6000 sccm. A plasma power may be between about 30 and 1500 W for a 300 nm substrate.

During optional step 210, excess reactive species are purged from the reaction chamber.

Steps 204-210 may constitute a deposition cycle; the deposition cycle may be repeated until the deposited material reaches a desired thickness.

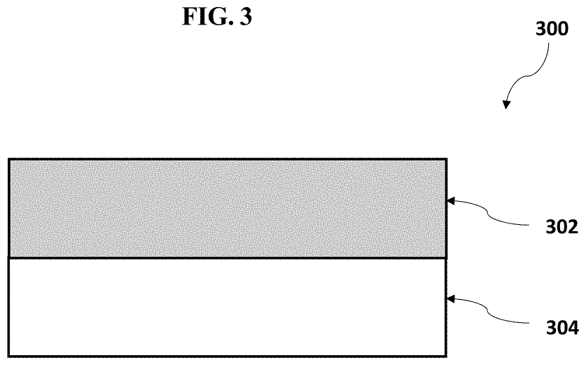

FIG. 3 illustrates a structure 300 in accordance in accordance with exemplary embodiments of the disclosure. Structure 300 includes substrate 304 and SiOC and/or SiOCN layer 302. Layer 302 can be formed, at least in part, according to a method as described herein, such as method 200. A SiOC layer is a layer which includes silicon, oxygen, carbon, and which may include impurities to the extent that such impurities do not materially change the characteristics of the SiOC layer. Similarly, a SiOCN layer is a layer which includes silicon, oxygen, carbon, nitrogen, and unavoidable impurities to the extent that such impurities do not materially change the characteristics of the SiOCN layer.

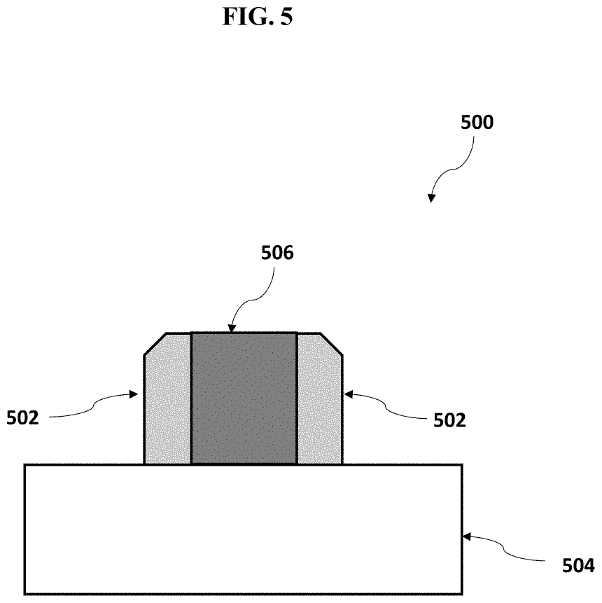

FIG. 5 illustrates a structure 500 in accordance with exemplary embodiments of the disclosure. Structure 500 includes substrate 504, feature 506, and SiOC and/or SiOCN spacers 502. Spacers 502 may be formed, at least in part, according to a method as described herein, such as method 200. Feature 506 may be, for example, a gate or a portion thereof, or other material deposited on substrate 504.

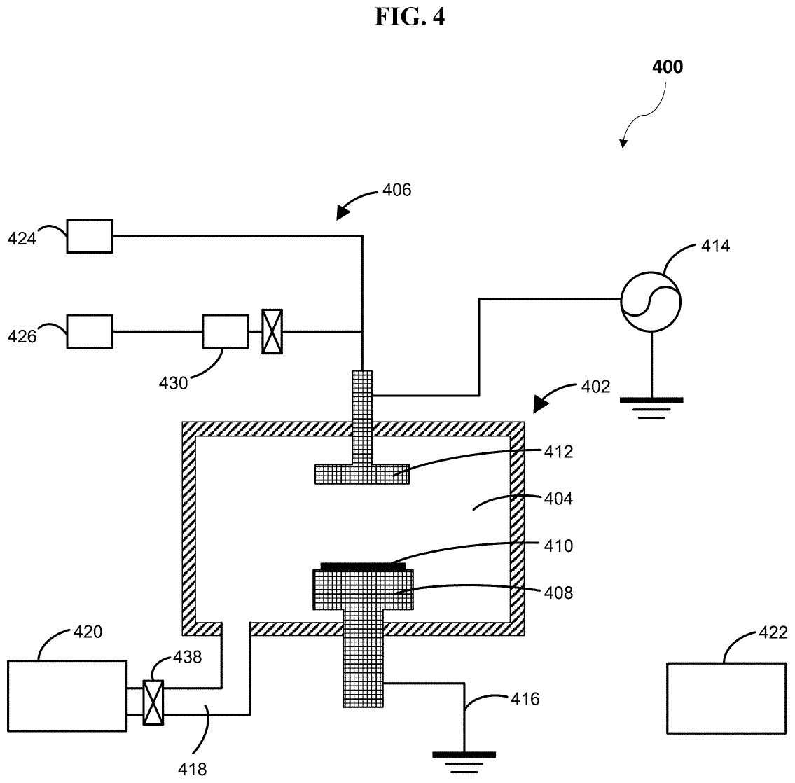

FIG. 4 illustrates a system 400 in accordance with exemplary embodiments of the disclosure. System 400 can be used to perform a method as described herein and/or to form a structure, or portion thereof, as described herein.

System 400 includes a reaction chamber 402, including a reaction space 404, a susceptor 408 to support a substrate 410, a gas distribution assembly 412, a gas supply system 406, a plasma power source 414, and a vacuum source 420. System 400 can also include a controller 422 to control various components of system 400.

Reaction chamber 402 can include any suitable reaction chamber, such as a plasma enhanced atomic layer deposition (PEALD) or a plasma enhanced chemical vapor deposition (PECVD) reaction chamber.

Susceptor 408 can include one or more heaters to heat substrate 410 to a desired temperature, such as a temperature noted herein. Further, susceptor 408 can form an electrode. In the illustrated example, susceptor 408 forms an electrode coupled to ground 416.

Gas distribution assembly 412 can distribute gas to reaction space 404. In accordance with exemplary embodiments of the disclosure, gas distribution assembly 412 includes a showerhead, which can form an electrode. In the illustrated example, gas distribution assembly 412 is coupled to a power source 414, which provides power to gas distribution assembly 412 to produce a plasma with reaction space 404 (between gas distribution assembly 412 and susceptor 408). Power source 414 can be, for example, an RF power supply.

Gas supply system 406 can include one or more gas sources 424 and 426, and a precursor source 430. Gas source 424 can include, for example, a vessel and a reactant gas as described herein. Precursor source 430 can include a vessel and a precursor as described herein. Vacuum source 420 can include any suitable vacuum pump, such as a dry pump. Vacuum source 420 can be coupled to reaction chamber 402 via line 418 and controllable valve 438.

Controller 422 can include electronic circuitry and software to selectively operate valves, heaters, thermocouples, pumps, and the like of system 400. Such circuitry and components operate to introduce precursors, reactants, and purge gases from sources 424, 426, and 430. Controller 422 can control timing of gas pulse sequences, temperature of the substrate and/or reaction chamber, pressure within the reaction chamber, and various other operations to provide proper operation of system 400. Controller 422 can include control software to electrically or pneumatically control valves to control flow of precursors, reactants and purge gases into and out of reaction chamber 402. Controller 422 can include modules such as a software or hardware component, e.g., a FPGA or ASIC, which performs certain tasks. A module can advantageously be configured to reside on the addressable storage medium of the control system and be configured to execute one or more processes.

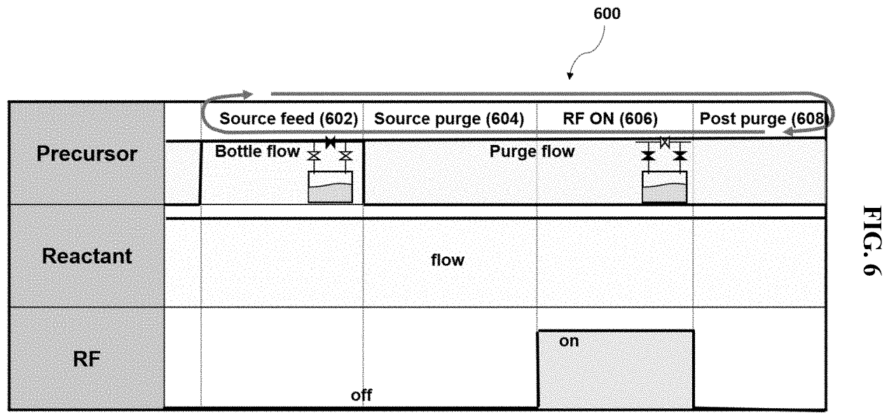

FIG. 6 illustrates a timing sequence 600 suitable for use with method 200. In timing sequence 600, in source feed step 602, a precursor is provided to the reaction chamber followed by a source purge step 604. Plasma is then applied in RF ON step 606, followed by post (plasma) purge step 608. Sequence steps 602-608 may be repeated until the deposited material reaches a desired thickness. As illustrated in timing sequence 600, reactant gas and a carrier/purge gas may be continuously flowed into the reaction space throughout the process.

In some embodiments, source feed step 602 corresponds to step 204; source purge step 604 corresponds to step 206; RF ON step 606 corresponds to step 208; and post purge step 608 corresponds to step 210 of method 200.

The example embodiments of the disclosure described above do not limit the scope of the invention since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of depositing a material on a surface of a substrate comprising:
providing the substrate within a reaction chamber;
providing a precursor represented by a chemical formula comprising silicon, at least one iodine, and at least one functional group comprising carbon and oxygen within the reaction chamber; and
providing a plasma within the reaction chamber.

2. The method of claim 1, wherein the oxygen is bonded to the silicon and the carbon.

3. The method of claim 1, wherein the at least one functional group comprising carbon and oxygen comprises one or more of a C1-C6 alkyl group and a C6 aryl group.

4. The method of claim 1, wherein the precursor is represented by a general formula I: 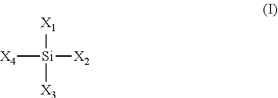
wherein at least one of X₁, X₂, X₃, and X₄ is iodine of the at least one iodine, and at least one of X₁, X₂, X₃, and X₄ is a functional group comprising carbon and oxygen of the at least one functionals group comprising carbon and oxygen.

5. The method of claim 4, wherein two of X₁, X₂, X₃, and X₄ are iodine of the at least one iodine, and two of X₁, X₂, X₃, and X₄ are a functional group containing carbon and oxygen of the at least one functional group comprising carbon and oxygen.

6. The method of claim 4, wherein three of X₁, X₂, X₃, and X₄ are iodine of the at least one iodine, and one of X₁, X₂, X₃, and X₄ is a functional group containing carbon and oxygen of the at least one functional group comprising carbon and oxygen.

7. The method of claim 1, wherein the functional group comprising carbon and oxygen comprises a C1-C6 alkoxide, or a C1-C4 alkoxide, or a C1-C3 alkoxide.

8. The method of claim 1, wherein the precursor comprises one or more of triethoxyiodosilane, iodotriphenoxysilane, [(triiodosilyl)oxy]benzene, triiodopropoxysilane, ethoxytriiodosilane, triiodomethoxysilane, diiododiphenoxysilane, diiododipropoxysilane, diiododimethoxysilane, iodotripropoxysilane, and iodotrimethoxysilane.

9. The method of claim 1, wherein the step of providing the plasma does not comprise providing an oxidant to the reaction chamber.

10. The method of claim 1, wherein the plasma is formed by flowing one or more of H₂, N₂, and NH₃ to the reaction chamber.

11. The method of claim 1, wherein the method comprises a plasma enhanced atomic layer deposition process.

12. The method of claim 1, further comprising purging the reaction chamber after providing the precursor.

13. The method of claim 1, further comprising purging the reaction chamber after providing the plasma.

14. The method of claim 13, wherein no RF power is provided to the reaction chamber while purging the reaction chamber.

15. The method of claim 1, wherein a temperature within the reaction chamber is between about 100 and about 500° C., between about 200 and about 400° C., or between about 250 and about 350° C.

16. The method of claim 1, wherein a pressure within the reaction chamber is between about 300 and 1000 Pa, or between about 1000 and about 3000 Pa.

17. The method of claim 1, wherein the material comprises one or more of silicon oxycarbide and silicon oxycarbide nitride.

18. The method of claim 1, wherein the method forms a spacer on a substrate.

19. A structure formed according to the method of claim 1.

20. A system for performing the method of claim 1.
